(19) United States
(12) Patent Application Publication
(10) Pub. No.: US 2022/0099861 A1
(43) Pub. Date: Mar. 31, 2022

(54) LINEARLY POLARIZED LIGHT CONVERSION ELEMENT, MANUFACTURING METHOD AND LINEARLY POLARIZED LIGHT CONVERSION SYSTEM

(71) Applicant: SOUTHERN UNIVERSITY OF SCIENCE AND TECHNOLOGY, Guangdong (CN)

(72) Inventors: Guixin LI, Guangdong (CN); Yanjun LIU, Guangdong (CN); Ningbin MAO, Guangdong (CN); Xuan LIU, Guangdong (CN)

(21) Appl. No.: 17/420,328

(22) PCT Filed: Jun. 13, 2019
(86) PCT No.: PCT/CN2019/091154

§ 371 Date: Jul. 1, 2021

(30) Foreign Application Priority Data
Jan. 4, 2019 (CN) 201910007580.X

(51) Int. Cl. G02B 1/00; G02B 5/30; G02B 27/28; G03F 7/20

(52) U.S. Cl. CPC G02B 1/002; G03F 7/70191; G02B 27/286; G02B 5/3025

(57) ABSTRACT

Provided are a linearly polarized light conversion element, a manufacturing method and a linearly polarized light conversion system. The linearly polarized light conversion element includes a substrate (1); a metasurface (2) located on the substrate (1); where the metasurface (2) includes at least one light field regulation control region (100), each light field regulation control region (100) includes at least one metasurface functional unit (20), the metasurface functional unit (20) includes an anisotropic sub-wavelength structure (201), and a long-axis direction of each sub-wavelength structure (201) in a same light field regulation control region (100) is the same.

### CROSS-REFERENCE TO RELATED APPLICATIONS

This is a National Stage Application filed under 35 U.S.C. 371 based on International Patent Application No. PCT/CN2019/091154, filed on Jun. 13, 2019, which claims priority to Chinese Patent Application No. 201910007580.X filed on Jan. 4, 2019, the disclosures of both of which are incorporated herein by reference in their entireties.

### TECHNICAL FIELD

Embodiments of the present application relate to the technical field of metasurfaces, and for example, to a linearly polarized light conversion element, a manufacturing method and a linearly polarized light conversion system.

### BACKGROUND

A Liquid crystal is a unique material with both liquid and crystal properties, and is widely applied to various liquid crystal displays. Under the action of an electric field, an arrangement structure of liquid crystal molecules will change, and meanwhile, the optical characteristics of the liquid crystal molecules will also change, which is also the basis of liquid crystal display. An ordered arrangement of the liquid crystal in a display screen is achieved through a pre-orientation on an interface between the liquid crystal and a substrate, and a liquid crystal orientation is a technology developed to achieve this purpose.

An existing liquid crystal orientation technology mainly includes a friction orientation method, a light-controlling orientation method and the like. The liquid crystal light-controlling orientation technology is a non-contact method for achieving the liquid crystal orientation through polarized light irradiation, is different from the friction orientation method, and has advantages of no pollution, no static electricity, easiness in achieving regional multi-orientation and the like. The light-controlling orientation technology uses a photosensitive material to undergo orientation light cross-linking, isomerization, or photo-cracking reactions under an ultraviolet polarized light irradiation so as to induce the orientation arrangement of the liquid crystal molecule.

However, most of existing liquid crystal light-controlling orientation technologies may only achieve an uniform orientation distribution. In order to achieve a controllable non-uniform orientation distribution, a complex optical system with large volume and high cost is often required, this controllable non-uniform orientation distribution needs to be completed through being exposed for many times, so that the manufacturing of a large-area and high-precision liquid crystal photonics device is not facilitated. In addition, an implementation scheme based on a spatial light modulator and a digital micro-mirror device is difficult to achieve the liquid crystal molecule orientation with a high spatial resolution (such as 1 μm)

### SUMMARY

In view of this, the present application provides a linearly polarized light conversion element, a manufacturing method and a linearly polarized light conversion system, so that the regulation control of a polarized direction of a beam is achieved, and a liquid crystal light-controlling orientation with a high spatial resolution can be conveniently achieved.

An embodiment of the present application provides a linearly polarized light conversion element. The linearly polarized light conversion element includes a substrate and a metasurface located on the substrate. The metasurface includes at least one light field regulation control region, each light field regulation control region includes at least one metasurface functional unit, each metasurface functional unit includes an anisotropic sub-wavelength structure, and a long-axis direction of each sub-wavelength structure in a same light field regulation control region is the same.

An embodiment of the present application provides a linearly polarized light conversion system. The linearly polarized light conversion system includes a laser, a beam shaper, a linear polarizer, and the linearly polarized light conversion element of any embodiment of the present application. The laser is configured to provide a laser light source. The beam shaper is configured to shape a laser emitted by the laser. The linear polarizer is configured to convert the shaped laser into linearly polarized incident light and propagate the linearly polarized incident light to the metasurface of the linearly polarized light conversion element.

An embodiment of the present application provides a manufacturing method of a linearly polarized light conversion element. The manufacturing method includes the following steps: a substrate is provided; and a metasurface is formed on the substrate, where the metasurface includes multiple metasurface functional units, each metasurface functional unit includes an anisotropic sub-wavelength structure, and the sub-wavelength structure is arranged based on a polarized direction of linearly polarized incident light and a linearly polarized state distribution of required emitted light.

### BRIEF DESCRIPTION OF DRAWINGS

The above and other features and advantages of the present application will become apparent to those of ordinary skill in the art by describing in detail exemplary embodiments of the present application with reference to the accompanying drawings below, in which:

FIG. 1 is a schematic diagram of a plane structure of a linearly polarized light conversion element according to an embodiment of the present application;

FIG. 2 is a schematic diagram of a cross-sectional structure of a linearly polarized light conversion element according to an embodiment of the present application:

FIG. 3 is a structural and principle schematic diagram of a linearly polarized light conversion system according to an embodiment of the present application;

FIG. 4 is a cross-shaped interference pattern of a vortex beam and reference light according to an embodiment of the present application:

FIG. 5 is a schematic diagram of an arrangement of a sub-wavelength structure according to an embodiment of the present application;

FIG. 6 is a flowchart of a manufacturing method of a linearly polarized light conversion element according to an embodiment of the present application:

FIG. 7 is a flowchart of a specific manufacturing method of a linearly polarized light conversion element according to an embodiment of the present application; and

FIGS. 8 to 12 are structural schematic diagrams corresponding to processes in a manufacturing method of a linearly polarized light conversion element according to an embodiment of the present application.

### DETAILED DESCRIPTION

Technical schemes of the present application are further described below by specific implementations in conjunction with the accompanying drawings. It should be understood that the specific embodiments described herein are merely intended to explain the present application and not to limit the present application. In addition, it should also be noted that, for ease of description, only some, not all, of the structures related to the present application are shown in the drawings.

At present, in a general light-controlling orientation method, firstly, a photosensitive molecule material (a light-controlling orientation layer) is coated on a substrate, and then ultraviolet polarized light is used for irradiating the light-controlling orientation layer to induce an orientation of liquid crystal molecules. A non-uniform orientation distribution may be achieved by a transformation optics reticle and multi-exposure method. A light-controlling orientation method based on a spatial light modulator (SLM) may flexibly control a polarized direction of local polarized light as required, to flexibly control the orientation of liquid crystal molecules. In addition, a micro-projection system based on a digital micro-mirror device (DMD) controls a single pixel (a single micro-mirror) on the DMD through a micro-electro-mechanical system (MEMS) to present different inversion states, so as to achieve a dynamic mask, and thus to achieve a dynamic control of an orientation structure pattern and an orientation direction of the liquid crystal.

However, the light-controlling orientation method described above requires a complex optical system with large volume and high cost, and needs to be completed through multi-exposure, so it is not conducive to achieve the manufacturing of a large-area and high-precision liquid crystal photonics device. In addition, an implementation scheme based on the spatial light modulator and the digital micro-mirror device is difficult to achieve the orientation of the liquid crystal molecules with a high spatial resolution (such as 1 μm).

An embodiment of the present application provides a linearly polarized light conversion element, to achieve the regulation and control of linearly polarized incident light in at least one polarized direction and to generate a vector light field distribution (at least one linearly polarized state distribution) with a sub-wavelength spatial resolution.

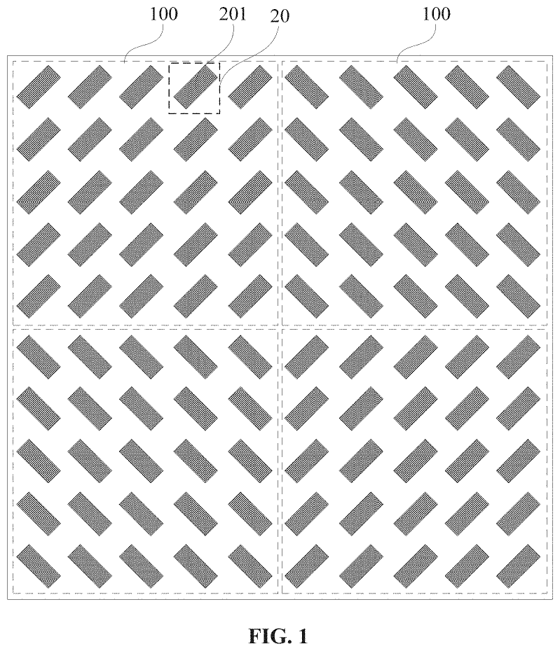

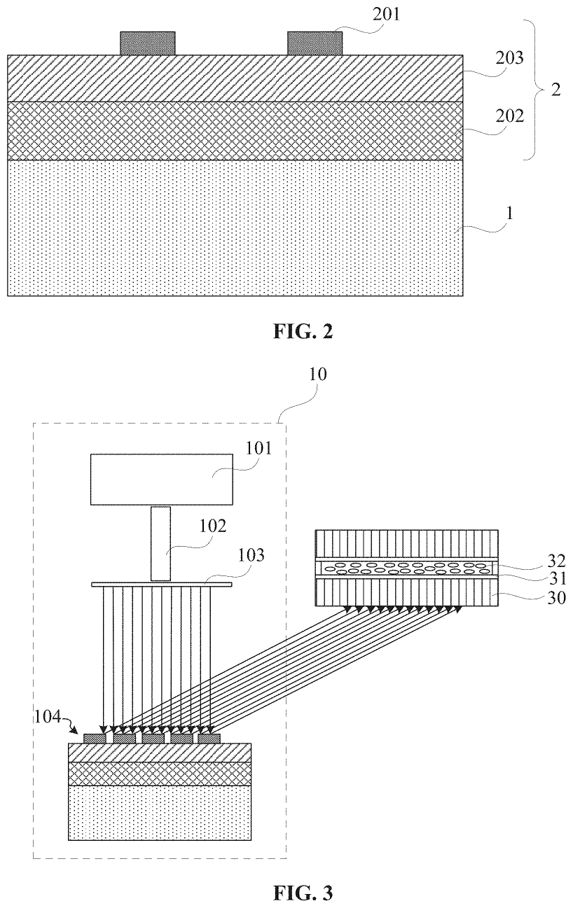

FIG. 1 is a schematic diagram of a plane structure of a linearly polarized light conversion element according to an embodiment of the present application. FIG. 2 is a schematic diagram of a cross-sectional structure of a linearly polarized light conversion element according to an embodiment of the present application. The linearly polarized light conversion element is applicable to the liquid crystal light-controlling orientation technology. As shown in FIGS. 1 and 2, the linearly polarized light conversion element provided in this embodiment includes a substrate 1 and a metasurface 2 located on the substrate 1. The metasurface 2 includes at least one light field regulation control region 100, each light field regulation control region 100 includes at least one metasurface functional unit 20, the metasurface functional unit 20 includes an anisotropic sub-wavelength structure 201, and a long-axis direction of each sub-wavelength structure 201 in a same light field regulation control region 100 is the same.

In this embodiment, the metasurface is an interface composed of the metasurface functional unit (sub-wavelength metasurface functional primitive) with a spatial variation, may effectively regulate and control the polarization, amplitude and phase of light, and may be used for achieving the high-efficiency optical holographic imaging, the high numerical aperture lens, the generation of an optical orbital angular momentum and the like. The two-dimensional property of the metasurface reduces the processing difficulty, has advantages of compact size and low loss, and is compatible with an existing complementary metal oxide semiconductor technology.

The light field regulation control region 100 described above may be understood as an area correspondingly divided according to an arrangement of the sub-wavelength structures 201 or a linearly polarized state distribution of required emitted light. In a same light field regulation control region 100, an arrangement of the sub-wavelength structure 201 is the same, and a polarized direction of light emitted through the light field regulation control region 100 is the same. The division of the light field regulation control region 100 facilitates the understanding of the overall arrangement of the sub-wavelength structures 201. The substrate 1 described above may be made of a transparent material such as silicon, glass or indium tin oxide (ITO), and the sub-wavelength structure 201 has a rod-like or an ellipse shape.

Based on the above technical scheme, the design principle of the linearly polarized light conversion element provided in this embodiment is as follows: according to the Berry geometric phase principle, namely, the interaction between circularly polarized light and the anisotropic sub-wavelength structure, a circularly polarized state of incident circularly polarized light may be reversed, and meanwhile, a geometric phase factor e^{-2iσφ} is introduced, where σ=±1 represents the circularly polarized state of the incident light, and p is an azimuth angle (an included angle between a long-axis direction of the sub-wavelength structure and a polarized direction of linearly polarized incident light incident to the linearly polarized light conversion element) of the anisotropic sub-wavelength structure on a plane. Therefore, the continuous regulation and control of the incident light phase from 0 to 2π may be achieved by simply changing the azimuth angle of the anisotropic sub-wavelength structure, and phase change symbols caused by incident light in different circularly polarized states are opposite. The incident linearly polarized light may be decomposed into left-handed circularly polarized light and right-handed circularly polarized light, the left-handed circularly polarized light and the right-handed circularly polarized light generate phase changes with a same size and opposite symbols through the sub-wavelength structure, the linearly polarized light may be formed again through synthesis, and the polarized direction is 2φ. It can be seen that, the polarized direction of the incident linearly polarized light may be regulated and controlled by simply changing the azimuth angle of the anisotropic sub-wavelength structure, and the azimuth angle of the sub-wavelength structure is related to the long-axis direction of the sub-wavelength structure and the polarized direction of the linearly polarized incident light, so that when the polarized direction of the linearly polarized incident light is constant, the polarized direction of the linearly polarized incident light may be regulated and controlled according to the linearly polarized state distribution of the required emitted light and through arranging the sub-wavelength structure, namely setting the long-axis direction of the sub-wavelength structure. Therefore, the emitted light satisfies the linearly polarized state distribution of the required emitted light.

In an embodiment, for a liquid crystal light-controlling orientation technology, a linearly polarized state distribution of emitted light used for exposing the light-controlling orientation layer may be determined according to a required orientation distribution of liquid crystal molecules, where an orientation direction of the liquid crystal molecules is the same as a linearly polarized direction of the emitted light. Therefore, an arrangement of the sub-wavelength structure is determined based on the linearly polarized state distribution of the emitted light, and the metasurface having the sub-wavelength structure with this arrangement is manufactured to obtain the linearly polarized light conversion element. Therefore, the orientation of the liquid crystal molecules can be controlled in a sub-wavelength scale, and a liquid crystal light-controlling orientation with a high spatial resolution is achieved.

In this embodiment, the linearly polarized light conversion element is designed by utilizing the metasurface, the metasurface is divided into at least one light field regulation control region, each light field regulation control region includes at least one metasurface functional unit, each metasurface functional unit includes the anisotropic sub-wavelength structure, and the long-axis direction (arrangement) of each sub-wavelength structure in the same light field regulation control region is the same. Therefore, after linearly polarized incident light in a same polarized direction is reflected or transmitted by the metasurface of the linearly polarized light conversion element, based on the arrangement of the sub-wavelength structure in each light field regulation control region, each light field regulation control region may convert a polarized direction of the correspondingly incident linearly polarized incident light into light in another polarized direction and emit it. Therefore, it is achieved that a polarized direction of a beam is regulated and controlled, and it may be stably and repeatedly used. Meanwhile, the arrangement of the sub-wavelength structure in the metasurface may be designed according to the linearly polarized state distribution of the required emitted light, so that the linearly polarized light conversion element of the present application is obtained and further the linearly polarized light conversion element may be used for converting linearly polarized incident light into at least one beam of linearly polarized light At least one exposure field of the light-controlling orientation layer is exposed once, so that at least one orientation of the light-controlling orientation layer may be achieved, and a corresponding orientation of the liquid crystal molecules is further achieved The process is simple, the cost is low, the orientation of the liquid crystal molecules can be controlled in the sub-wavelength scale, and the liquid crystal light-controlling orientation with the high spatial resolution is achieved.

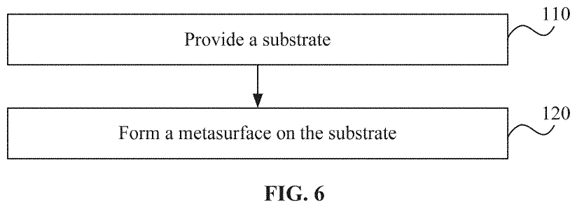

In an embodiment, with continued reference to FIG. 1, the at least one light field regulation control region 100 includes two or more light field regulation control regions 100 (4 light field regulation control regions 100 are shown in FIG. 4). Long-axis directions of sub-wavelength structures 201 in different light field regulation control regions 100 are different.

Therefore, after a same linearly polarized incident light simultaneously passes through different light field regulation control regions 100 of the metasurface, light in a direction different from the polarized direction of the linearly polarized incident light may be emitted, and the polarized direction of the emitted light corresponding to different light field regulation control regions 100 is different, so that multiple vector light fields may be simultaneously generated, the number of single exposure samples is increased, and the production efficiency is improved. In an embodiment, when the linearly polarized light conversion element is used for performing the light-controlling orientation on the liquid crystal molecules, a non-uniform orientation distribution of the liquid crystal molecules may be achieved through only one exposure, so that the number of exposures is reduced, and the process of the light-controlling orientation is simplified. Meanwhile, based on the Berry geometric phase principle described above, it can be seen that the continuous regulation and control of the incident light phase from 0 to 2π may be achieved by simply changing the azimuth angle of the anisotropic sub-wavelength structure, and different phases of the incident light may cause deflection of reflected light at different angles, so that the deflection angle of the reflected light can be adjusted through setting the azimuth angle of the anisotropic sub-wavelength structure. According to this embodiment, in a case where the azimuth angle of the sub-wavelength structure is constant, after an emitted angle of emitted light projected to an exposure field of the light-controlling orientation layer is determined, an incident angle of the linearly polarized incident light incident to the linearly polarized light conversion element (the metasurface) may be determined in combination with ray optics and the generalized reflection law. Therefore, the adjustment of the emitted angle of the emitted light may be achieved by adjusting the incident angle of the linearly polarized incident light, to achieve the exposure of the exposure field of the light-controlling orientation layer and the orientation of the corresponding liquid crystal molecules.

It should be noted that FIG. 1 is merely intended to exemplarily illustrate the arrangement of the sub-wavelength structure, and the specific arrangement is determined according to the actual situation.

In addition, the linearly polarized light conversion element described above may reflect or transmit the linearly polarized incident light to achieve the regulation and control of the polarized direction of the linearly polarized incident light, and correspondingly, the metasurface in the linearly polarized light conversion element may be a reflective metasurface or a transmissive metasurface. In an embodiment, for the reflective metasurface, the metasurface/metasurface functional unit may include a structure (referring to FIG. 2) in which a metal reflective layer 202, a dielectric layer 203 and a metal sub-wavelength structure 201 are laminated, or the metasurface functional unit may include a structure in which a metal reflective layer and a metal sub-wavelength structure are laminated, or the metasurface functional unit may include a structure in which a metal reflective layer and a dielectric sub-wavelength structure are laminated. For the transmissive metasurface, the metasurface functional unit may include the dielectric sub-wavelength structure. According to the embodiments of the present application, a specific film layer structure of the metasurface/metasurface functional unit is not limited, and is determined according to the actual situation.

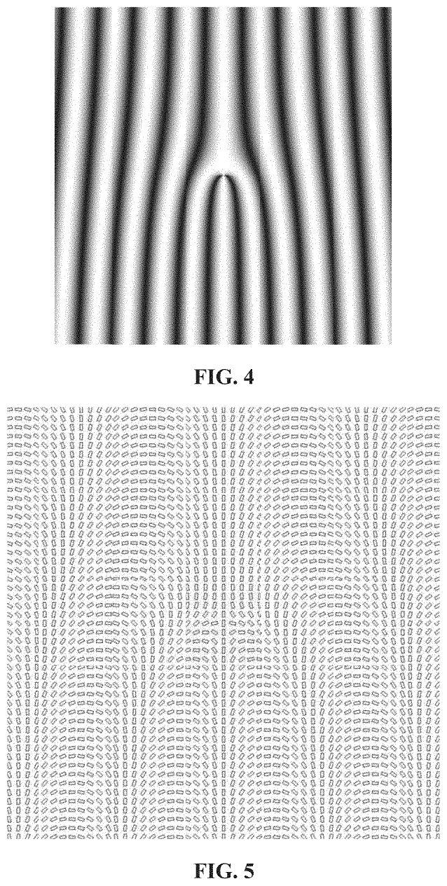

Based on the above embodiments, another embodiment of the present application provides a linearly polarized light conversion system. As shown in FIG. 3, a linearly polarized light conversion system 10 includes a laser 101, a beam shaper 102, a linear polarizer 103, and the linearly polarized light conversion element 104 provided in the above embodiments.

The laser 101 is configured to provide a laser light source; the beam shaper 102 is configured to shape a laser emitted by the laser 101; the linear polarizer 103 is configured to convert the shaped laser into linearly polarized incident light and propagate the linearly polarized incident light to the metasurface of the linearly polarized light conversion element 104.

The beam shaper 102 described above may be a Gaussian flat-top beam converter or a spatial filtering collimating system.

In an embodiment, the linearly polarized light conversion system 10 may be a liquid crystal light-controlling orientation system. In this case, with reference to FIG. 3, after passing through the beam shaper 102 and the linear polarizer 103, the laser emitted by the laser 101 forms linearly polarized incident light to be incident to the metasurface of the linearly polarized light conversion element 104. Referring to the functions of the linearly polarized light conversion element 104 provided in any one of the above embodiments, the linearly polarized light conversion element 104 may convert linearly polarized incident light into emitted light which satisfies the required linearly polarized distribution state, and project the emitted light to a light-controlling orientation layer 31 which is spin-coated on a conductive glass substrate 30 in advance, so that the orientation of the light-controlling orientation layer 31 is completed. Therefore, a high-resolution spatial arrangement distribution of liquid crystal molecules 32 between the light-controlling orientation layers 31 is achieved.

The linearly polarized light conversion system provided in this embodiment includes the linearly polarized light conversion element provided in the embodiments of the present application, and has corresponding functions and beneficial effects.

In addition, a special liquid crystal photonics device (such as a beam splitter) manufactured by using the linearly polarized light conversion system described above may generate, regulate and control a special light field (such as a vortex beam, a Bessel beam, an Airy beam and the like) through the manufactured liquid crystal photonics device.

In an embodiment, an example in which the linearly polarized light conversion system of the present application manufactures a liquid crystal photonics device capable of generating, regulating and controlling a vortex beam is given for illustration. The vortex beam has a spiral isophase surface, each photon has an orbital angular momentum of mh, where m is a topological quantum number, may be any integer, and represents an orbital angular momentum index, and different values of m correspond to mutually orthogonal angular momentum states, and h is a reduced Planck constant. The center of the vortex beam is a phase singularity where the amplitude is zero, thus presenting an annular light field distribution. The vortex beam has wide application in the fields of optical tweezers, optical communication, super-resolution imaging, astronomical observation and the like.

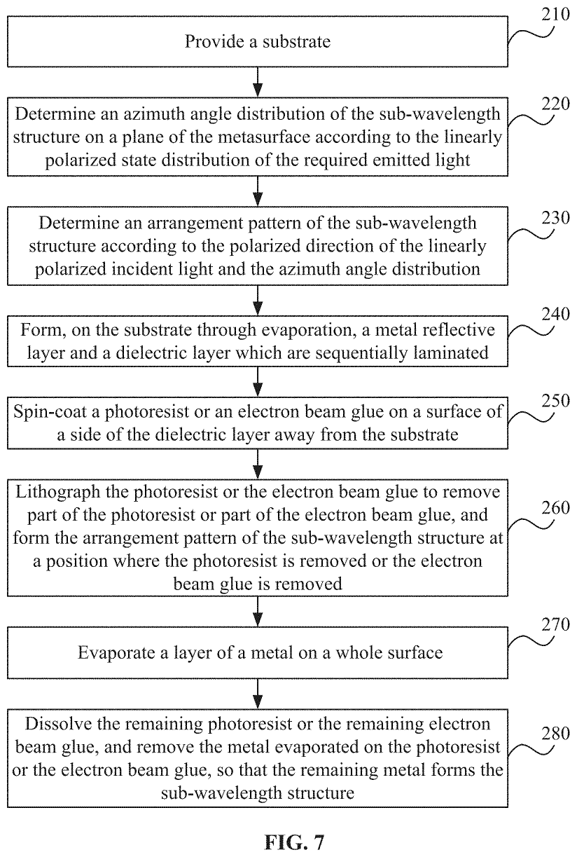

Based on the holographic principle, when the vortex beam and the reference light (such as a Gaussian beam, an ideal plane wave) are interfered at an angle, a fork-shaped interference pattern (as shown in FIG. 4) is obtained. At this time, an orientation distribution of liquid crystal molecules in the liquid crystal photonics device to be manufactured should be arranged in the fork-shaped interference pattern shown in FIG. 4, an arrangement pattern (as shown in FIG. 5) of the sub-wavelength structure may be designed based on the fork-shaped interference pattern, and then the liquid crystal molecules are oriented on the metasurface having the sub-wavelength structure shown in FIG. 5, so that the orientation distribution of the liquid crystal molecules may present the fork-shaped interference pattern shown in FIG. 4, and the vortex light may be generated by irradiating of the reference light.

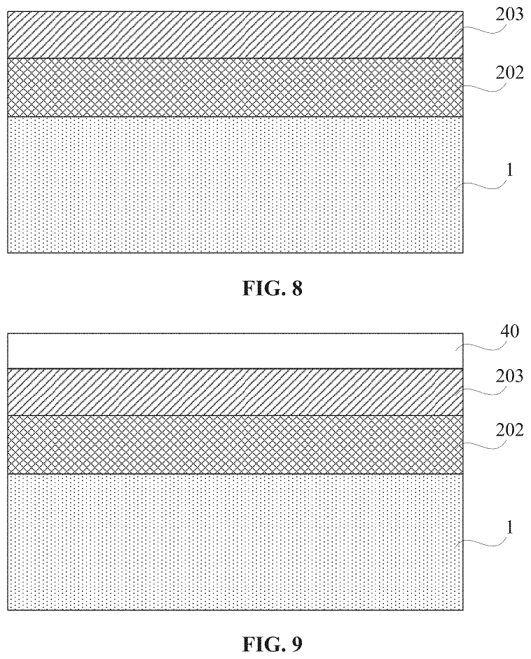

Based on the above embodiments, another embodiment of the present application provides a manufacturing method of a linearly polarized light conversion element. As shown in FIG. 6, the manufacturing method of a linearly polarized light conversion element includes step 110 and step 120.

In step 110, a substrate is provided.

A substrate 1 may be made of a transparent material such as silicon, glass or ITO.

In step 120, a metasurface is formed on the substrate.

The metasurface includes multiple metasurface functional units, the metasurface functional unit includes an anisotropic sub-wavelength structure, and the sub-wavelength structure is arranged based on a polarized direction of linearly polarized incident light and a linearly polarized state distribution of required emitted light.

In an embodiment, the step in which the metasurface is formed on the substrate may include the following steps: an azimuth angle distribution of the sub-wavelength structure on a plane of the metasurface is determined according to the linearly polarized state distribution of the required emitted light, where an azimuth angle is an included angle between a long-axis direction of the sub-wavelength structure and a polarized direction of linearly polarized incident light incident to the linearly polarized light conversion element; an arrangement pattern of the sub-wavelength structure is determined according to the polarized direction of the linearly polarized incident light and the azimuth angle distribution; and at least the sub-wavelength structure is formed on the substrate based on the arrangement pattern of the sub-wavelength structure.

In an embodiment, the step in which at least the sub-wavelength structure is formed on the substrate based on the arrangement pattern of the sub-wavelength structure may include the following steps: a metal reflective layer and a dielectric layer which are sequentially laminated are formed on the substrate through evaporation; a photoresist or an electron beam glue is spin-coated on a surface of a side of the dielectric layer away from the substrate; the photoresist or the electron beam glue is lithographed to remove part of the photoresist or part of the electron beam glue, and the arrangement pattern of the sub-wavelength structure is formed at a position where the photoresist is removed or the electron beam glue is removed; a layer of a metal is evaporated on a whole surface; and the remaining photoresist or the remaining electron beam glue is dissolved, and the metal evaporated on the photoresist or the electron beam glue is removed, so that the remaining metal forms the sub-wavelength structure.

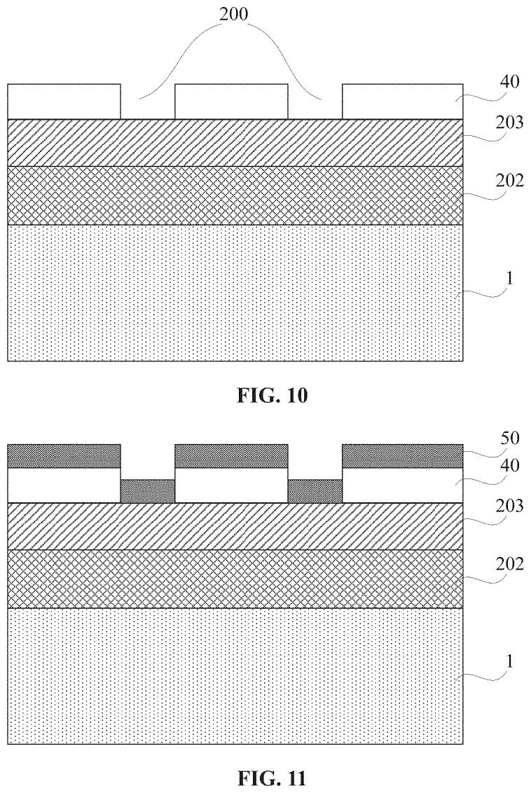

Based on the above technical schemes, in an application embodiment of the present application, as shown in FIG. 7, the manufacturing method of a linearly polarized light conversion element includes steps 210 to 280.

In step 210, a substrate is provided.

In step 220, an azimuth angle distribution of the sub-wavelength structure on a plane of the metasurface is determined according to the linearly polarized state distribution of the required emitted light, where an azimuth angle is an included angle between a long-axis direction of the sub-wavelength structure and a polarized direction of linearly polarized incident light incident to the linearly polarized light conversion element.

The polarized direction of light emitted from each region on the metasurface may be determined according to the linearly polarized state distribution of the required emitted light. Based on the Berry geometric phase principle in the above embodiments, it can be seen that the polarized direction of the emitted light is 2 times of the azimuth angle of the sub-wavelength structure, so that the azimuth angle distribution of the sub-wavelength structure on the plane of the metasurface may be determined.

In step 230, an arrangement pattern of the sub-wavelength structure is determined according to the polarized direction of the linearly polarized incident light and the azimuth angle distribution.

Since the azimuth angle is the included angle between the long-axis direction of the sub-wavelength structure and the polarized direction of the linearly polarized incident light incident to the linearly polarized light conversion element, in a case where the polarized direction of the linearly polarized incident light is constant, the long-axis direction of the sub-wavelength structure in each region on the metasurface may be determined according to the azimuth angle distribution obtained in the step 220, and thus the arrangement pattern of the sub-wavelength structure is determined.

In step 240, a metal reflective layer and a dielectric layer which are sequentially laminated are formed on the substrate through evaporation.

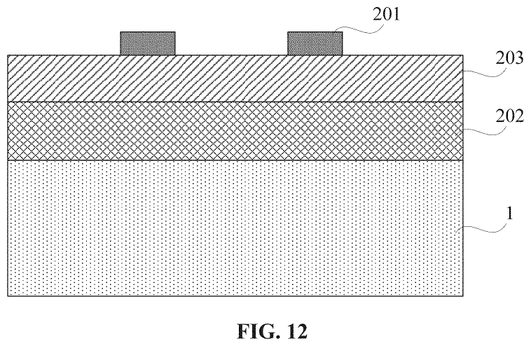

Referring to FIG. 8, a metal reflective layer 202 and a dielectric layer 203 which are sequentially laminated are formed on the substrate 1 by evaporation, where the metal reflective layer 202 may be made of aluminum or gold, and the dielectric layer 203 may be made of silicon dioxide. In an embodiment, the metal reflective layer 202 and the dielectric layer 203 may be sequentially evaporated on the substrate 1 by using a thermal evaporation or electron beam evaporation technology.

In step 250, a photoresist or an electron beam glue is spin-coated on a surface of a side of the dielectric layer away from the substrate.

As shown in FIG. 9, a photoresist 40 or an electron beam glue is spin-coated on a surface of a side of the dielectric layer 203 away from the substrate 1.

In step 260, the photoresist or the electron beam glue is lithographed to remove part of the photoresist or part of the electron beam glue, and the arrangement pattern of the sub-wavelength structure is formed at a position where the photoresist is removed or the electron beam glue is removed.

In an embodiment, as shown in FIG. 10, the photoresist 40 is exposed using ultraviolet lithography, or the electron beam glue is exposed using electron beam lithography, and then the exposed photoresist 40 or the exposed electron beam glue is removed using a corresponding developing solution to form an arrangement pattern 200 of the sub-wavelength structure at a position where the photoresist 40 is removed or the electron beam glue is removed, and finally, the remaining photoresist 40 or the remaining electron beam glue is cleaned.

In step 270, a layer of a metal is evaporated on a whole surface.

In an embodiment, as shown in FIG. 11, an electron beam evaporation process or a thermal evaporation process is used for evaporating a layer of a metal 50 on a surface of the dielectric layer 203 and a surface of the remaining photoresist 40 or a surface of the remaining electron beam glue.

In step 280, the remaining photoresist or the remaining electron beam glue is dissolved, and the metal evaporated on the photoresist or the electron beam glue is removed, so that the remaining metal forms the sub-wavelength structure.

In an embodiment, as shown in FIG. 12, a corresponding glue removing solution is used for removing the remaining photoresist 40 or the remaining electron beam glue, so that the metal located on the remaining photoresist 40 or the remaining electron beam glue falls off, and thus the layer of the metal on the surface of the dielectric layer 203 is retained to form the sub-wavelength structure 201.

According to the manufacturing method of a linearly polarized light conversion element described above, the linearly polarized light conversion element with the reflective metasurface may be manufactured. The above embodiments merely exemplarily describe the manufacturing method of the reflective metasurface having the metal reflective layer 202, the dielectric layer 203 and the metal sub-wavelength structure 201. It should be noted that the reflective metasurface of the linearly polarized light conversion element in the present application may further include a structure in which a metal reflective layer and a metal sub-wavelength structure are laminated, or a structure in which a metal reflective layer and a dielectric sub-wavelength structure are laminated. The specific manufacturing method may be reasonably deduced based on the manufacturing method of the linearly polarized light conversion element in this embodiment, which will not be repeated herein.

In addition, an embodiment of the present application further provides a manufacturing method of a linearly polarized light conversion element having a transmissive metasurface, and the manufacturing method includes steps 310 to 390 described below.

In step 310, a transparent substrate is provided.

In step 320, an azimuth angle distribution of a sub-wavelength structure on a plane of a metasurface is determined according to a linearly polarized state distribution of required emitted light.

In step 330, an arrangement pattern of the sub-wavelength structure is determined according to a polarized direction of linearly polarized incident light and the azimuth angle distribution.

In step 340, a dielectric layer is evaporated or deposited on the transparent substrate.

The dielectric layer may be made of silicon, silicon nitride or titanium dioxide.

In step 350, a photoresist or an electron beam glue is spin-coated on a surface of a side of the dielectric layer away from the substrate.

In step 360, the photoresist or the electron beam glue is lithographed to remove part of the photoresist or part of the electron beam glue, and the arrangement pattern of the sub-wavelength structure is formed at a position where the photoresist is removed or the electron beam glue is removed.

In step 370, a protective layer is evaporated on a whole surface.

The protective layer may be made of chromium.

In step 380, the remaining photoresist or the remaining electron beam glue is dissolved, and the protective layer evaporated on the photoresist or the electron beam glue is removed.

In step 390, the remaining protective layer is taken as a mask film, a dielectric layer not covering the protective layer is etched, and the remaining protective layer is removed, so that the remaining dielectric layer forms the sub-wavelength structure.

In an embodiment, the linearly polarized state distribution of the required emitted light is determined by an orientation direction of the liquid crystal to be oriented. Therefore, the linearly polarized state distribution of the required emitted light may be determined based on the orientation direction of the liquid crystal to be oriented, so that a liquid crystal light-controlling orientation system for liquid crystal light-controlling orientation is manufactured, the orientation of liquid crystal molecules may be controlled in the sub-wavelength scale, and the liquid crystal light-controlling orientation with the high spatial resolution is achieved.

In addition, in this application, the optical reflective efficiency of the metasurface may be improved by adjusting the parameter (such as length and width) of the sub-wavelength structure based on the surface plasmon resonance principle, so that the utilization rate of the linearly polarized incident light is improved, and the loss of the linearly polarized incident light is reduced.

1. A linearly polarized light conversion element, comprising:
a substrate; and
a metasurface located on the substrate;
wherein the metasurface comprises at least one light field regulation control region, each light field regulation control region comprises at least one metasurface functional unit, each metasurface functional unit comprises an anisotropic sub-wavelength structure, and a long-axis direction of each sub-wavelength structure in a same light field regulation control region is the same.

2. The element of claim 1, wherein the at least one light field regulation control region comprises at least two light field regulation control regions, and long-axis directions of sub-wavelength structures in different light field regulation control regions are different.

3. The element of claim 1, wherein each metasurface functional unit comprises one of the following: a structure in which a metal reflective layer, a dielectric layer, and a metal sub-wavelength structure are laminated; a structure in which a metal reflective layer and a metal sub-wavelength structure are laminated; a structure in which a metal reflective layer and a dielectric sub-wavelength structure are laminated; or a dielectric sub-wavelength structure.

4. A linearly polarized light conversion system, comprising a laser, a beam shaper, a linear polarizer, and the linearly polarized light conversion element of claim 1;
wherein the laser is configured to provide a laser light source; the beam shaper is configured to shape a laser emitted by the laser, and the linear polarizer is configured to convert the shaped laser into linearly polarized incident light and propagate the linearly polarized incident light to the metasurface of the linearly polarized light conversion element.

5. The system of claim 4, wherein the linearly polarized light conversion system is a liquid crystal light-controlling orientation system.

6. A manufacturing method of a linearly polarized light conversion element, comprising:
providing a substrate; and
forming a metasurface on the substrate, wherein the metasurface comprises a plurality of metasurface functional units, each metasurface functional unit comprises an anisotropic sub-wavelength structure, and the sub-wavelength structure is arranged based on a polarized direction of linearly polarized incident light and a linearly polarized state distribution of required emitted light.

7. The method of claim 6, wherein forming the metasurface on the substrate comprises:
determining, according to the linearly polarized state distribution of the required emitted light, an azimuth angle distribution of the sub-wavelength structure on a plane of the metasurface, wherein an azimuth angle is an included angle between a long-axis direction of the sub-wavelength structure and a polarized direction of linearly polarized incident light incident to the linearly polarized light conversion element;
determining an arrangement pattern of the sub-wavelength structure according to the polarized direction of the linearly polarized incident light and the azimuth angle distribution; and
forming at least the sub-wavelength structure on the substrate based on the arrangement pattern of the sub-wavelength structure.

8. The method of claim 7, wherein forming at least the sub-wavelength structure on the substrate based on the arrangement pattern of the sub-wavelength structure comprises:
forming, on the substrate through evaporation, a metal reflective layer and a dielectric layer which are sequentially laminated;
spin-coating a photoresist or an electron beam glue on a surface of a side of the dielectric layer away from the substrate;
lithographing the photoresist or the electron beam glue to remove part of the photoresist or part of the electron beam glue, and forming the arrangement pattern of the sub-wavelength structure at a position where the photoresist is removed or the electron beam glue is removed;
evaporating a layer of a metal on a whole surface; and
dissolving a remaining photoresist or a remaining electron beam glue, and removing the metal evaporated on the photoresist or the electron beam glue, so that a remaining metal forms the sub-wavelength structure.

9. The method of claim 7, wherein forming at least the sub-wavelength structure on the substrate based on the arrangement pattern of the sub-wavelength structure comprises:
evaporating or depositing a dielectric layer on a transparent substrate;
spin-coating photoresist or electron beam glue on a surface of a side of the dielectric layer away from the substrate;
lithographing the photoresist or the electron beam glue to remove part of the photoresist or part of the electron beam glue, and forming the arrangement pattern of the sub-wavelength structure at a position where the photoresist is removed or the electron beam glue is removed;
evaporating a protective layer on a whole surface;
dissolving a remaining photoresist or a remaining electron beam glue, and removing the protective layer evaporated on the photoresist or the electron beam glue; and
taking a remaining protective layer as a mask film, etching a dielectric layer not covering the protective layer, and removing the remaining protective layer, so that a remaining dielectric layer forms the sub-wavelength structure.

10. The method of claim 6, wherein the linearly polarized state distribution of the required emitted light is determined by an orientation direction of a liquid crystal to be oriented.

11. A linearly polarized light conversion system, comprising a laser, a beam shaper, a linear polarizer, and the linearly polarized light conversion element of claim 2;
wherein the laser is configured to provide a laser light source; the beam shaper is configured to shape a laser emitted by the laser, and the linear polarizer is configured to convert the shaped laser into linearly polarized incident light and propagate the linearly polarized incident light to the metasurface of the linearly polarized light conversion element.

12. The system of claim 11, wherein the linearly polarized light conversion system is a liquid crystal light-controlling orientation system.

13. A linearly polarized light conversion system, comprising a laser, a beam shaper, a linear polarizer, and the linearly polarized light conversion element of claim 3;
wherein the laser is configured to provide a laser light source; the beam shaper is configured to shape a laser emitted by the laser, and the linear polarizer is configured to convert the shaped laser into linearly polarized incident light and propagate the linearly polarized incident light to the metasurface of the linearly polarized light conversion element.

14. The system of claim 13, wherein the linearly polarized light conversion system is a liquid crystal light-controlling orientation system.
